(19) United States
(12) Patent Application Publication
(10) Pub. No.: US 2018/0056577 A1
(43) Pub. Date: Mar. 1, 2018

(54) FLEXIBLE MOLD WITH VARIABLE THICKNESS

(71) Applicant: National Cheng Kung University, Tainan City (TW)

(72) Inventors: Yung-Chun LEE, Tainan City (TW); Yi-Chun TSAI, Tainan City (TW); Chun-Ying WU, Tainan City (TW); Wei-Hsiang SU, Tainan City (TW); Shao-Hsuan HUANG, Tainan City (TW); Ke-Chang LU, Tainan City (TW)

(21) Appl. No.: 15/685,793

(22) Filed: Aug. 24, 2017

(30) Foreign Application Priority Data
Aug. 25, 2016 (TW) 105127611

(51) Int. Cl. B29C 59/02; B29C 45/76

(52) U.S. Cl. CPC B29C 59/022; G03F 7/0002; B29C 45/76

(57) ABSTRACT

The present invention is a flexible mold with variable thickness which is a mold body with nano-imprinting micro-structure, and the mold body is gradually thickened from its periphery to the middle. When the flexible mold with variable thickness of the present invention is subjected to a force or displaced, a larger amount of compression may be produced to cause a larger contact pressure between the micro-structure at the bottom of the mold body and the imprinted object, and to control the amount of deformation of the mold body upon stripping by the thickness difference of the mold body for overcoming the previous defect caused by the excessive draft angle or sharp pressure release.

### BACKGROUND OF THE INVENTION

### 1. Field of the Invention

The present invention relates to an imprinting mold for nano-imprinting technique, more particularly, to a flexible mold with variable thickness having an imprinting mechanism and system capable of precisely controlling pressure distribution to monitor the flow pattern of polymer resistance layer during the imprinting process and further to ensure the thickness and uniformity of polymer residue layer in large area.

### 2. Description of the Prior Art

Nano-imprinting technique has developed for 20 years, with a large impact and effect on the academia and industry at home and abroad. Many new methods, techniques, materials, machines and even professional manufacturers have therefore emerged and seek for possible industrial applications actively. To be honest, there are many momentous technique bottlenecks in nano-imprinting technique to be overcome commonly by academia and industry; these bottlenecks mainly comprise: (1) production mode, cost and service life of the imprinting mold; (2) control on the thickness and uniformity of imprinting residue layer in large area; (3) control on accuracy of repetitive or multi-layer alignment; (4) overall process yield and cost competitiveness etc.

The core concept of nano-imprinting technique is to substitute the complex optical lithography technique with simple mechanical and mechanical principles for duplicating the micro/nano-structure with large area and small feature dimension. Its core technique: contact, pressure, formation, stripping, physical and chemical changes of polymer material against temperature and light may be accompanied. The challenge for nano-imprinting technique is that it has to use mechanical mode with the consideration of the dimensions of two poles: formed area with large dimension (4″, 6″, 8″), structural characteristic of small line width (μm, sub-μm and nm). Currently there are various nano-imprinting techniques, however, the common basic characteristic of the most is to form uniformly a polymer material between a piece of mold and a piece of substrate; the formed polymer layer should replicate the micro/nano-structure of the mold surface faithfully and the thickness of the residual layer within its imprinting area has to be less than required, for example 10˜100 nm.

Observing from the present nano-imprinting system design and imprinting technique in academia and industry, it is surprised that mechanical control is lacked during all the pressing process, such as average pressure on the mold during pressing process allowing an average contact pressure between the mold and substrate; additionally, during stripping, defect caused by sharp pressure release often create the fracture of micro-structure.

Thus the process forming polymer resistance layer by the existed nano-imprinting machine design and imprinting technique has a limited and feeble ability on controlling the final residual layer; it may possibly one of the key bottlenecks for the nano-imprinting technique and its industrial applications.

### SUMMARY OF THE INVENTION

To solve the problems of above traditional technique, the purpose of the present invention is to provide a flexible mold with variable thickness capable of providing precise mechanical control during the nano-imprinting process for accurate transferring and distribution on the pressed polymer layer material.

To solve the problems of above traditional technique, another purpose of the present invention is to provide a flexible mold with variable thickness that can absorb the unevenness of the substrate, distribute the pressure uniformly and drive the polymer layer to flow controllably.

To achieve above purposes, the flexible mold with variable thickness of the present invention mainly comprises a mold body. The lower surface of the mold body is an imprinting face having a nano-imprinting micro-structure; the mold body is gradually thickened from its periphery to above the middle. Due to the larger thickness at the center of the mold body, a larger amount of compression may be produced to cause a larger contact pressure between the micro-structure at the bottom of the mold body and the imprinted object.

Wherein the mold body is molded from a thermalsetting silicone material.

### BRIEF DESCRIPTION OF THE DRAWINGS

With reference to the detailed descriptions and accompanying figures related with the present invention, the technical content and purpose effects of the present invention will be further understood; the related figures are:

FIG. 1 is a side view of the flexible mold with variable thickness of the present invention;

FIG. 2 is a schematic view (1) of the use status for the flexible mold with variable thickness of the present invention;

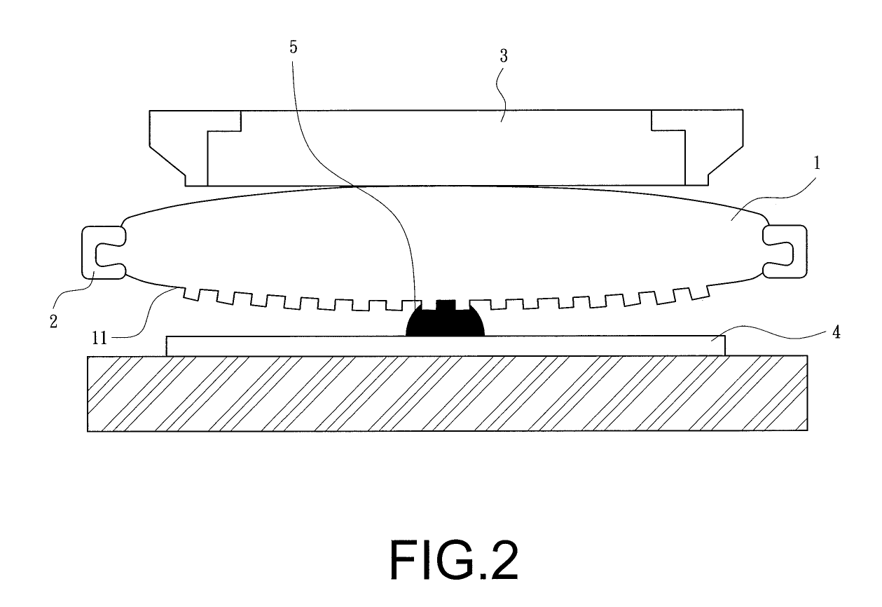

FIG. 3 is a schematic view (2) of the use status for the flexible mold with variable thickness of the present invention;

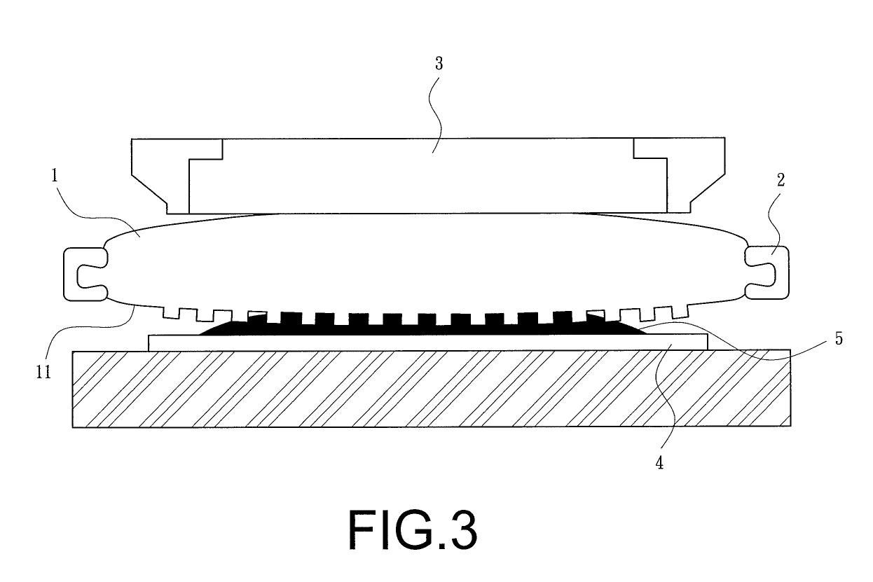

FIG. 4 is a schematic view (3) of the use status for the flexible mold with variable thickness of the present invention;

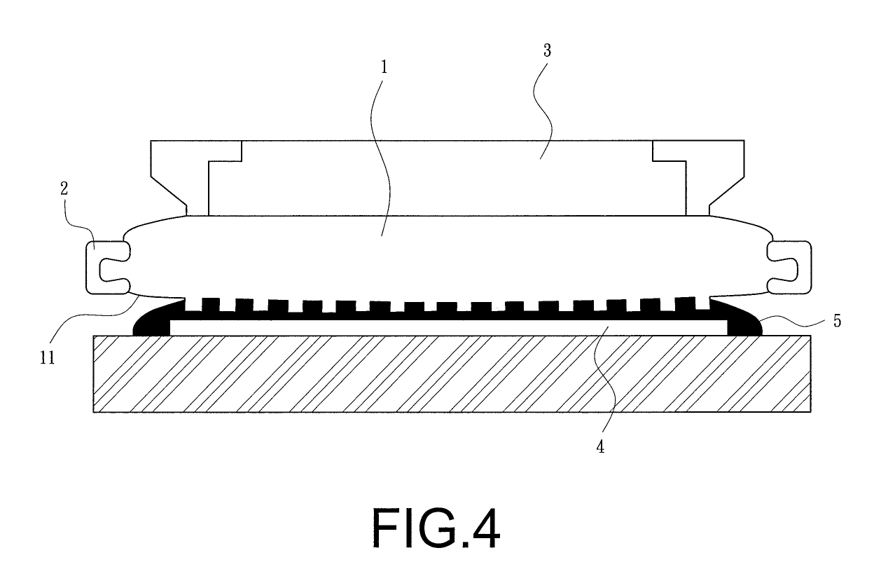

FIG. 5 is a side view of another embodiment of the flexible mold with variable thickness of the present invention;

FIG. 6 is a schematic view (1) of the user status in another embodiment of the flexible mold with variable thickness of the present invention;

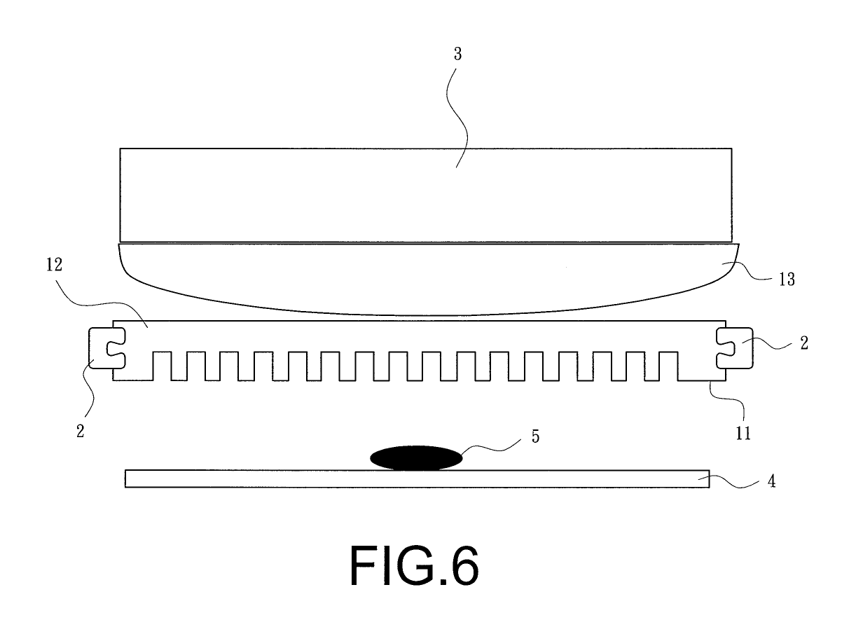

FIG. 7 is a schematic view (2) of the user status in another embodiment of the flexible mold with variable thickness of the present invention.

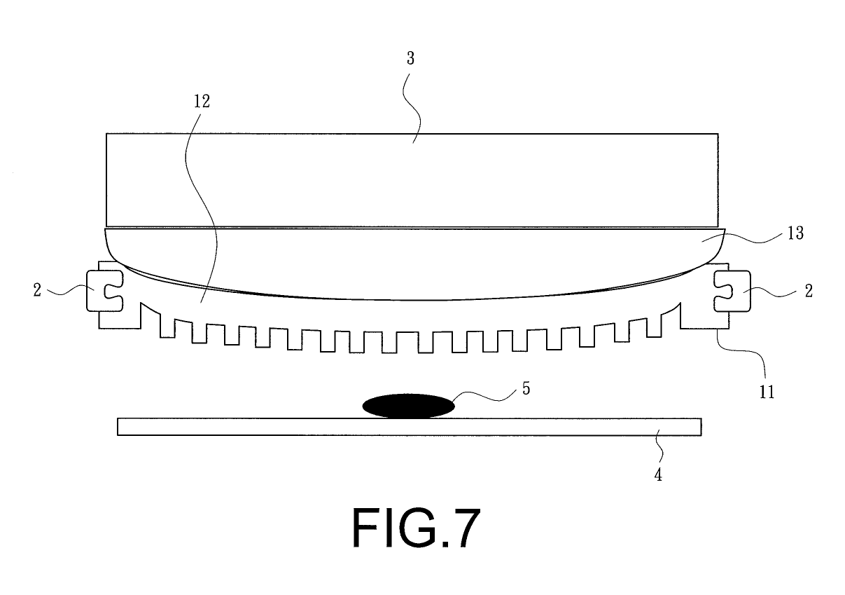

### SYMBOL DESCRIPTION OF MAIN ELEMENT

1 mold body
11 imprinting face
12 imprinting mold
13 soft mold
2 metal ring
3 hard backplate
4 substrate
5 resist glue

### DETAILED DESCRIPTION OF THE PREFERRED EMBODIMENT

The following will describe specific embodiments to illustrate the implementation of the present creation, which are not used to limit the scope of the present invention.

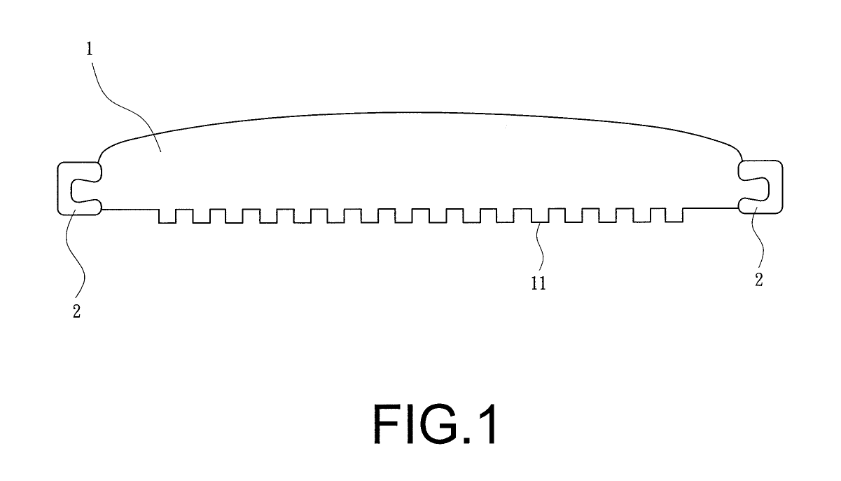

With reference to FIG. 1˜4, in the first embodiment of the flexible mold with variable thickness of the present invention, a mold body 1 of the flexible mold with variable thickness of the present invention is formed by combining a silicon crystal round mold having micro-structure with a stainless steel mold having curved surface and casting them with a thermalsetting silicone material; the bottom of the mold body 1 is an imprinting face 11 having nano-imprinting micro-structure and the mold body 1 is thickened gradually from the periphery of the mold body 1 to above the middle.

The periphery of the mold body 1 of the flexible mold with variable thickness of the present invention is mainly secured by a metal ring 2, and then applying a force or displacement to the upper surface of the mold body 1 with a hard backplate 3 to cause the imprinting face 11 of the mold body 1 to deform and protrude, the central area of the imprinting face 11 being in contact with a resist glue 5 on a substrate 4. Subsequently, the relative distance between the hard backplate and the substrate is further shortened, and since the mold body 1 has a large thickness at the center, it may produce a large amount of compression when being pressed by the hard backplate 3 and the substrate 4 to cause a larger contact pressure between the imprinting face 11 of the mold body 1 and the substrate 4, thus forcing the resist glue 5 to fill into the recess of the micro-structure and to extrude the redundant resist glue 5 to flow outward to the edge of the substrate 4.

During the imprinting process, the distribution of contact pressure can be controlled by the approaching rate and displacement from the hard backplate 3 to the substrate 4. Then the resist glue 5 is cured by UV radiation and heating to complete the nano-imprinting formation flow for the micro-structure. Finally, the draft angle and separation rate can be controlled by the rate and displacement of the hard backplate 3 away from the substrate 4, so that defect of the fracture of micro-structure caused by the sharp release in force can be avoided during stripping in traditional techniques.

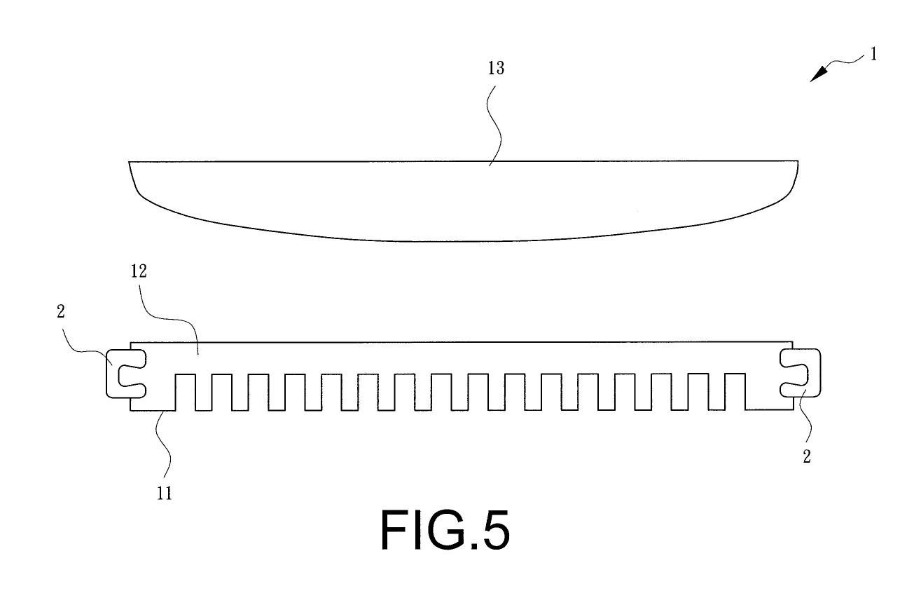

With reference to FIG. 5˜7, in the second embodiment of the flexible mold with variable thickness of the present invention, a mold body 1 of the flexible mold with variable thickness of the present invention includes an imprinting mold 12 and soft mold 13; the lower surface of the imprinting mold 12 is the imprinting face 11 having nano-imprinting micro-structure and the soft mold 13 is an elastomer thickened gradually from the periphery to the middle; the soft mold 13 is gradually thickened from the periphery of the soft mold 13 to below the middle of the soft mold 13.

The present embodiment mainly uses the metal ring 2 to hold and fix the periphery of the imprinting mold 12, and then combing the soft mold 13 with the hard backplate 3 and applying a displacement or force onto the imprinting mold 12 to cause the imprinting face 11 of the imprinting mold 12 to deform and protrude, thus the central area of the imprinting face 11 contacting with the resist glue 5 on the substrate 4. Subsequently, the relative distance between the hard backplate 3 and the substrate 4 is further shortened, and since the soft mold 13 has a large thickness at the center, it may produce a large amount of compression when the imprinting mold 12 is pressed to cause a larger contact pressure between the imprinting face 11 of the imprinting mold 13 and the substrate 4, thus forcing the resist glue 5 to fill into the recess of the micro-structure and to extrude the redundant resist glue 5 to flow outward to the edge of the substrate 4.

As described above, compared with traditional technique, the flexible mold with variable thickness of the present invention has following characteristics and effects:

1. The present invention forms a contact pressure distribution featured as strong in the center but weak around between the mold body and the substrate by the different stresses and strain produced upon deformation in the imprinting process through the thickness difference, forcing the resist glue to flow outward from the center of the substrate and thus achieving the purpose of uniform distribution while solving the drawback of wasting glue materials in tradition spin-coating process.

2. The present invention can control the deformation amount of the mold body by applying displacement or force onto the mold body during imprinting process through the thickness difference of the mold body, and further achieve the control on the contact pressure during the imprinting process, thus achieving the purposes of high uniformity of micro-structure resulted from imprinting and minimal thickness of the bottom residual layer.

3. The present invention controls the deformation amount of the mold body upon stripping by the thickness difference of the mold body to improve the fracture defect of micro-structure caused by excessive draft angle and sharp release of pressure.

The above-mentioned detailed description aims to specifically illustrate one practicable embodiment of the present invention, but the embodiment is not for limiting the patent scope of the present invention and all equivalent embodiments or modifications made without departing from the spirit of the present invention shall be contained within the patent scope of the present invention. Many changes and modifications in the above described embodiment of the invention can, of course, be carried out without departing from the scope thereof. Accordingly, to promote the progress in science and the useful arts, the invention is disclosed and is intended to be limited only by the scope of the appended claims.

What is claimed is:

1. A flexible mold with variable thickness comprises:
a kernel body gradually thickened from its periphery to the middle, and the bottom of the kernel body has a nano-imprinting micro-structure.

2. The flexible mold with variable thickness according to claim 1, wherein the kernel body is molded from thermalsetting silicone material, a photocurable silicone material, a rubber material, a plastic material.

3. The flexible mold with variable thickness according to claim 1, wherein the mold body is gradually thickened from its periphery to above the middle.

4. A flexible mold with variable thickness comprises:
a kernel body comprising:
an imprinting mold having a nano-impriting micro-structure at the lower surface thereof;
a soft mold is a elastomer varied gradually from the periphery to middle, the soft mold pressing against the imprinting mold from the lower surface of the imprinting mold.

5. The flexible mold with variable thickness according to claim 4, wherein the soft mold and the imprinting mold are molded from a thermalsetting silicone material, a photocurable silicone material, a rubber material, a plastic material.

6. The flexible mold with variable thickness according to claim 4, wherein the soft mold body is gradually thickened from its periphery to below the middle.
